(19) United States
(12) Patent Application Publication
(10) Pub. No.: US 2010/0126549 A1
(43) Pub. Date: May 27, 2010

(54) SOLAR CELL MODULE WITH A LUMINOUS ELEMENT

(76) Inventor: Jae-Hak Ryu, Goyang-Si Gyeonggi-Do (KR)

Correspondence Address: IPLA P.A., 3550 WILSHIRE BLVD., 17TH FLOOR, LOS ANGELES, CA, 90010, US

(21) Appl. No.: 12/376,530

(22) PCT Filed: Feb. 26, 2007
(86) PCT No.: PCT/KR07/00969

§ 371 Date: Feb. 5, 2009

(30) Foreign Application Priority Data
Aug. 7, 2006 (KR) 10-2006-0074226
Feb. 26, 2007 (KR) PCT/KR2007/000969

(51) Int. Cl. H01L 31/042

(52) U.S. Cl. 136/244

(57) ABSTRACT

A solar cell module having an integrally-arranged light emitting device, including a reinforced glass; upper and lower EVA films underlying the reinforced glass; a plurality of solar cells arranged between the upper and lower EVA films and connected in series or parallel by conductive ribbons to convert solar energy into electric energy; a backing sheet underlying the lower EVA film; and a control box arranged under the backing sheet, and including a battery or capacitor and a circuit board. The light emitting device is arranged under the reinforced glass, wherein the circuit board controls electric energy, which is charged in the battery or capacitor by the solar cells at daytime, to be applied to the light emitting device at night to turn on the light emitting device. The circuit board has a switch unit, and by operating the switch unit, charges electric energy to the battery or capacitor if the electric energy is inputted from the solar cells, and discharges the electric energy from the battery or capacitor to turn on the light emitting device if no electric energy is inputted from the solar cells.

### TECHNICAL FIELD

The present invention relates to a solar cell module having an integrally-arranged light emitting device, and more particularly, to a solar cell module having an integrally-arranged light emitting device and provided to a building, a house, a road and the like, in which the light emitting device can be turned on at night using electric energy charged by solar cells, such that the solar cell module can turn on and off without having to use an additional lighting device or energy source in order to promote the aesthetic appearance of the city.

### BACKGROUND ART

In general, a solar cell module is a semiconductor device for converting light energy into electric energy using photoelectric effect, and recently gaining attention as it can provide non-polluting, noiseless and infinite energy. In particular, considering that Tokyo protocol for regulating the amount of greenhouse gas emission such as carbon dioxide and methane gas was came into effect on Feb. 16, 2005 and Korea imports 80% or more of energy sources, solar energy is being promoted as one of important alternative energy resources. The solar cell module generates electric power necessary for a user using a plurality of solar cells, which are connected in series and/or parallel via conductive ribbons, such that the user can use the electric power as a supply voltage. To date, the solar cell module is installed in various areas such as a building roof, a building wall, a remote area, an island, a park and a traffic light to serve as a power source or widely used as a power source of a guide board.

### DISCLOSURE OF INVENTION

### Technical Problem

However, the solar cell module of the prior art is designed to electric energy from solar energy in the daytime and thus useless in the night or in the middle of night. The inventor has studied for a long time to use a solar cell module in the night, and thus invented a novel solar cell module with a light emitting device mounted thereon, in which at least a portion of electric power generated by the solar cell module is charged, and the light emitting device of the solar cell module is turned on using the charged electric energy. As a result, it is possible to promote the aesthetic appearance of the city in the night or the middle of night as well as to turn on, for example, a guide board without an additional light source or power source so as to be more easily indicated by drivers and the like.

### Technical Solution

The present invention has thus been made to solve the aforementioned problems with the prior art, and an aspect of the invention is to provide a solar cell module capable of converting light energy into electric energy and charging at least a portion of the electric energy in a rechargeable battery (or capacitor) in the daytime, such that a light emitting device equipped in the solar cell module can be turned on to emit light using the charged electric energy.

Another invention of the invention is to promote the aesthetic appearance of the city by using the solar cell module for lighting or decorating purposes in the night or in the middle of night without having to use an additional light source or power source.

Further invention aspect of the invention is to seal the light emitting device with Ethylene Vinyl Acetate (EVA) films, a silicone, an epoxy resin and the like to waterproof the same in order to prevent malfunctions of the solar cell module owing to the permeation of rainwater and the like.

Yet another invention of the invention is to enable a circuit board to automatically discern between day and night (or middle of night) based upon energy input from solar cells without having to use a timer or sensor, and automatically supply charged electric power to the light emitting device to emit light.

### ADVANTAGEOUS EFFECTS

According to the present invention, following effects can be produced.

First, the invention provides a solar cell module capable of converting light energy into electric energy and charging at least a portion of the electric energy in a rechargeable battery (or capacitor) in the daytime, such that a light emitting device equipped in the solar cell module can be turned on to emit light using the charged electric energy.

Second, the invention advantageously promotes the aesthetic appearance of the city by using the solar cell module for lighting or decorating purposes in the night or in the middle of night without having to use an additional light source or power source.

Third, it is possible to seal the light emitting device with Ethylene Vinyl Acetate (EVA) films, a silicone, an epoxy resin and the like to waterproof the same in order to prevent malfunctions of the solar cell module owing to the permeation of rainwater and the like.

Fourth, a circuit board can automatically discern between day and night (or middle of night) based upon energy input from solar cells without having to use a timer or sensor, and automatically supply charged electric power to the light emitting device to emit light.

### BRIEF DESCRIPTION OF THE DRAWINGS

FIG. 1 is a perspective view illustrating a solar cell module having a light emitting device according to a first embodiment of the invention;

FIG. 2 is a perspective view illustrating the solar cell module having the light emitting device according to the first embodiment of the invention;

FIG. 3 is a perspective view illustrating a solar cell module having a light emitting device according to a second embodiment of the invention;

FIG. 4 is a perspective view illustrating a solar cell module having a light emitting device according to a third embodiment of the invention; and

FIG. 5 is a reference view illustrating the solar cell module of the invention, in which LEDs can be installed in spaces between solar cells of the solar cell module.

### MAJOR REFERENCE NUMERALS OF THE DRAWINGS

110, 210, 310: reinforced glass
112: through hole
120, 220, 320: upper EVA film
130, 230, 330: solar cell
140, 240, 340: lower EVA film
150, 250, 350: backing sheet
160, 260: LED
360: EL light
170, 270, 370: control box
172, 272, 372: circuit board
174, 274, 373: rechargeable cell or capacitor

### BEST MODE FOR CARRYING OUT THE INVENTION

According to an embodiment of the invention to realize any of the aforementioned aspects, there is provided a solar cell module having a light emitting device arranged integrally therein. The solar cell module includes a reinforced glass; upper and lower Ethylene Vinyl Acetate (EVA) films underlying the reinforced glass; a plurality of solar cells arranged between the upper and lower EVA films and connected in series or parallel by conductive ribbons to convert solar energy into electric energy; a backing sheet underlying the lower EVA film; a control box arranged under the backing sheet, and including a battery or capacitor and a circuit board; and at least one LED, as the light emitting device, arranged under the reinforced glass, wherein the circuit board controls electric energy, which is charged in the battery or capacitor by the solar cells at daytime, to be applied to the LED at night to turn on the LED.

Preferably, some of the solar cells may be dedicated for the LED, such that and electric power generated by the dedicated cells is charged and then exclusively used to power the LED.

According to another embodiment of the invention, the reinforced glass may have at least one through hole, in which the LED is inserted.

Preferably, the solar cell module may further include a transparent silicone resin for molding the LED inserted into the reinforced glass in order to waterproof the LED.

More preferably, the solar cell module may further include a silicone or epoxy resin for molding the control box to waterproof the battery or capacitor and the circuit board arranged in the control box.

According to a preferred embodiment of the invention, the circuit board may have a switch unit, and through operations of the switch unit, charges electric energy to the battery or capacitor if the electric energy is inputted from the solar cells, and discharges the electric energy from the battery or capacitor to turn on the LED if no electric energy is inputted from the solar cells.

According to another embodiment of the invention to realize any of the aforementioned aspects, there is provided a solar cell module having a light emitting device arranged integrally therein. The solar cell module includes a reinforced glass; upper and lower EVA films underlying the reinforced glass; a plurality of solar cells arranged between the upper and lower EVA films and connected in series or parallel by conductive ribbons to convert solar energy into electric energy; a backing sheet underlying the lower EVA film; a control box arranged under the backing sheet and including a battery or capacitor and a circuit board; and at least one electro-luminescent (EL) device, as the light emitting device, arranged between the upper and lower EVA films, wherein the circuit board controls electric energy, which is charged in the battery or capacitor by the solar cells at daytime, to be applied to the LED at night to turn on the LED.

Preferably, some of the solar cells may be dedicated for the EL device, such that and electric power generated by the dedicated cells is charged and then exclusively used to power the EL device.

### MODE FOR THE INVENTION

Exemplary embodiments of the invention will now be described in detail with reference to the accompanying drawings.

### Solar Cell Module Having Light Emitting Device According to 1st Embodiment

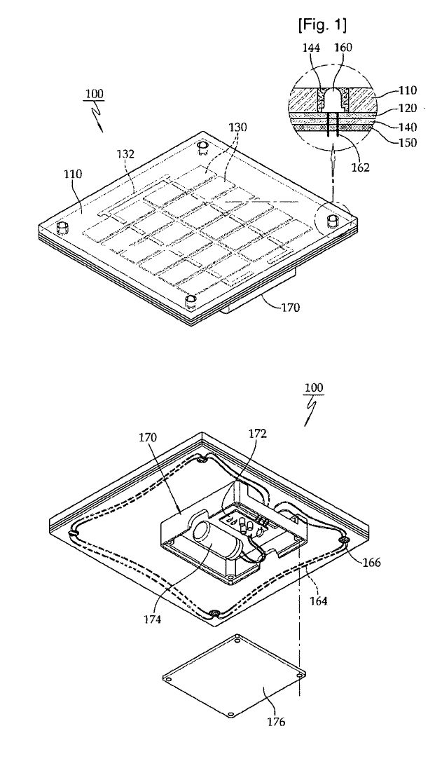

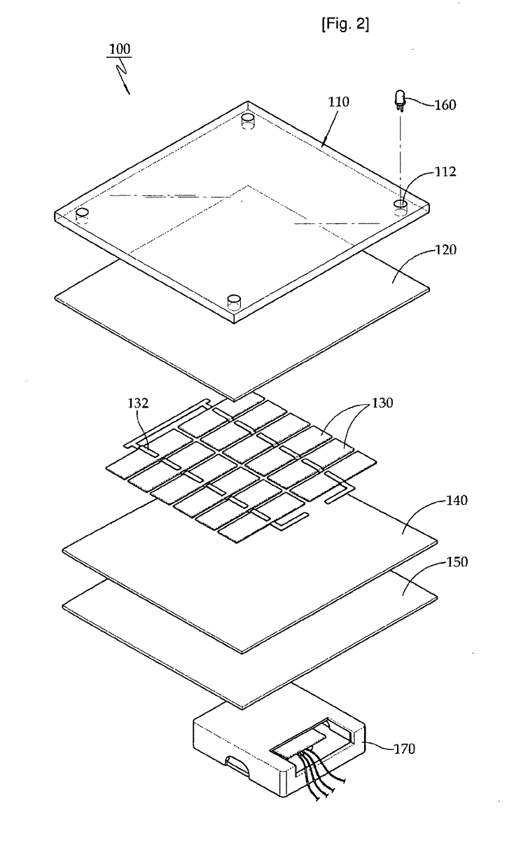

FIG. 1 is a perspective view illustrating a solar cell module having a light emitting device according to a first embodiment of the invention, and FIG. 2 is a perspective view illustrating the solar cell module having the light emitting device according to the first embodiment of the invention.

Referring to FIGS. 1 and 2, the solar cell module 100 includes a reinforced glass 110, Light Emitting Diodes (LEDs) 160 (or one LED) arranged in a corner of the reinforced glass 110, upper and lower Ethylene Vinyl Acetate (EVA) films 120 and 140 stacked under the reinforced glass 110, a plurality of solar cells 130 arranged between the upper and lower EVA films 120 and 140 and connected in series or parallel by conductive ribbons 132 to convert light into electric energy, a backing sheet 150 underlying the lower EVA film and a control box 170 arranged under the backing sheet 150 and having a battery or capacitor 170 and a circuit board 172.

The reinforced glass 110 acts to protect the solar cells 130 from external impact and the like, and may be fabricated in various shapes including a circle, a semicircle, a quadrangle and the like according to the design of the solar cell module. The reinforced glass shown in FIG. 1 has a rectangular plate shape.

Referring to FIG. 2, the upper EVA film 120 and the lower EVA film 140 are stacked under the reinforced glass 110. Here, the EVA film is a copolymer of ethylene and vinyl acetate, excellent in transparency, buffering property, elasticity and tensile stress. Between the upper and lower EVA films 120 and 140 having such characteristics, the solar cells 130 are arranged and connected in series or parallel by the conductive ribbons 132. The backing sheet 150 underlying the lower EVA film 140 performs functions of waterproof, insulation and ultraviolet ray blocking. As shown in FIGS. 1 and 2, the control box 170 is attached to the underside of the backing sheet 150. The control box 170 includes the rechargeable battery or capacitor 170 for charging and discharging electric energy generated by the solar cells 130 and the circuit board 172 for controlling the turning on/off of the LEDs 160. After the rechargeable battery or capacitor 170 and the circuit board 172 are arranged inside the control box 170, a molding can be preferably carried out using a silicone or epoxy resin to give waterproof ability to the control box 170 in order to prevent, for example, the circuit board from being exposed to rainwater and the like which otherwise may cause malfunction. The circuit board 172 applies electric power, which is generated by the solar cells 130 and charged, for example, in the capacitor 174 in the daytime, to the LEDs 160 in the nighttime so that the LEDs 160 can emit light.

Referring to FIG. 2, the reinforced glass 130 is perforated with through holes 112 (or one through hole) into which the LEDs 130 can be inserted, respectively. Preferably, after the LEDs 130 are inserted into the through holes 112 of the reinforced glass 130, transparent silicone resin 114 may be injected into the through holes 112 to waterproof the LEDs 130. As shown in FIG. 1, each of the LEDs 130 has terminals 162 extended through the upper EVA film 120, the lower EVA film 140 and the backing sheet 150 to protrude out of the underside of the backing sheet 150. The protruding terminals 162 are connected to the circuit board 172 by conductors 164 made of a conductive material. The circuit board 172 supplies a voltage from the capacitor 172 to the LEDs 130 through the conductors 164 to turn on the LEDs 130. The circuit board 172 has a switch unit, and through the operation of the switch unit, charges electric energy to the capacitor 174 and so on if the electric energy is inputted from the solar cells 130, and discharges electric energy from the capacitor 174 and so on to turn on the LEDs 160 if no electric energy is inputted from the solar cells 130. As a result, the circuit board 172 can automatically discern between day and night based upon the energy input from the solar cells 130 and thus automatically turn on the LEDs, in particular, at night without using any timer or sensor.

Solar Cell Module Having Light Emitting Device According to 2nd Embodiment

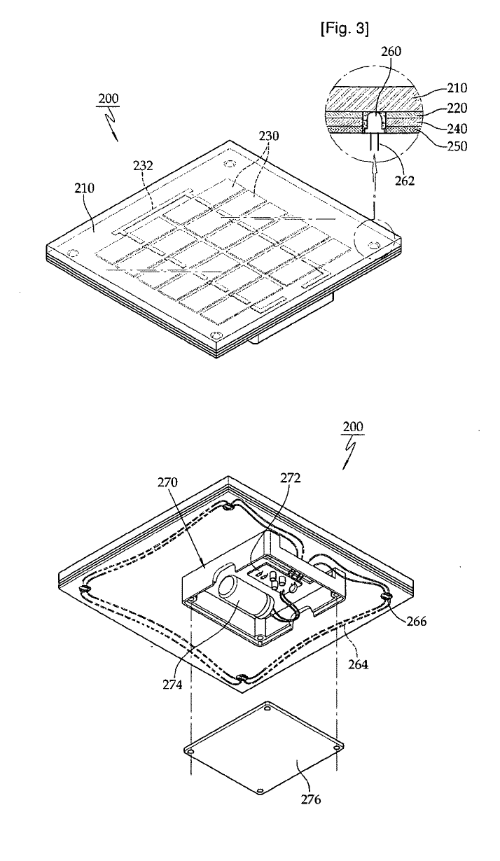

FIG. 3 is a perspective view illustrating a solar cell module having a light emitting device according to a second embodiment of the invention. In the solar cell module 200 according to the second embodiment of the invention, through holes are not perforated in a reinforced glass 210 but LEDs 260 are arranged under the reinforced glass 210. That is, as shown in FIG. 3, through holes are formed in preset portions of an upper EVA film 220, a lower EVA film 240 and a backing sheet 250 corresponding to mounting positions of the LEDs 260, and the LEDs 260 are arranged respectively in the through holes in position to contact the reinforced glass 210. The through holes are also molded with a silicone or epoxy resin to fix the LEDs 260. Since the solar cell module of this embodiment has substantially the same structure as in the aforementioned first embodiment except for the mounting structure of the LEDs 260, detailed description of the same parts will be omitted.

Solar Cell Module Having Light Emitting Device According to 3rd Embodiment

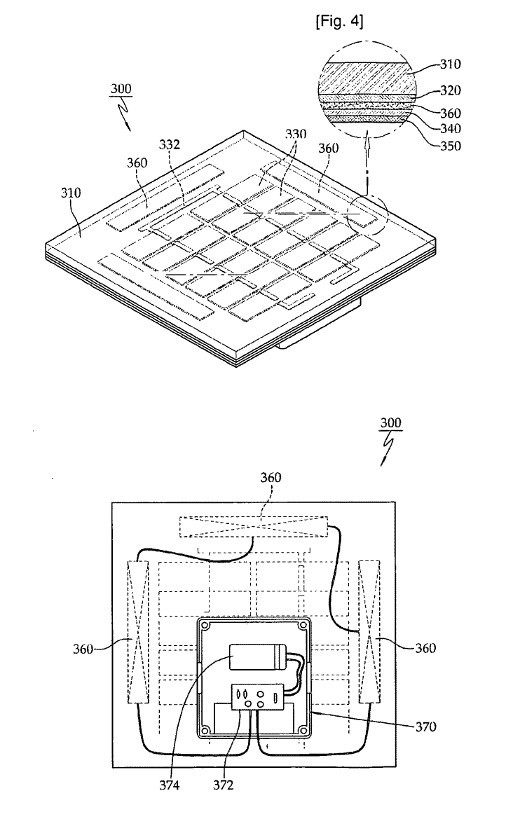

FIG. 4 is a perspective view illustrating a solar cell module having a light emitting device according to a third embodiment of the invention. In the solar cell module 300 according to the third embodiment of the invention, solar cells 330 are arranged between upper and lower EVA films 320 and 340 which underlie a reinforced glass 310. In addition, electro-luminescent (EL) devices 360 (or one EL device) are arranged together. As in the aforementioned embodiments, electric power charged in a capacitor 374 by the solar cells 330 in the daytime can be applied to the EL devices 360 to emit light.

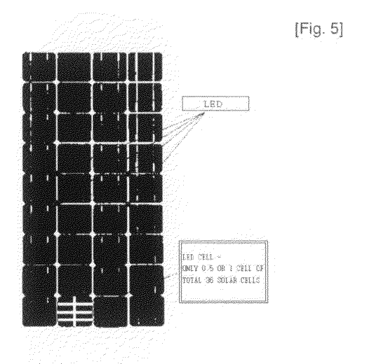

FIG. 5 is a reference view illustrating a solar cell module of the invention, in which LEDs are installed in spaces between solar cells of the solar cell module. In the case of a large scale solar cell module, a certain amount of spaces exist in solar cell arrays. As indicated with arrows, the LEDs are mounted in the spaces in a structure as mentioned above in the first or second embodiment in order to maximize the space efficiency of the solar cell module.

LED Dedicated Cell of Solar Cell Module

In any of the aforementioned solar cell modules according to the first to third embodiments, some of the solar cells 130 are dedicated for the LEDs, and electric energy generated by the dedicated cells is charged and then exclusively used to power the LEDs 160.

Typically, solar cells are grouped according to sizes such as 4, 5 and 6 inches, and generate different amounts of average power according to the sizes. For example, a 4-inch solar cell generates an average electric power of 1.44 W (Wmp: 0.48V, Imp: 3.0 A), a 5-inch solar cell generates an average electric power of 2.3 W (Vmp: 0.48V, Imp: 4.8 A), and a 6-inch solar cell generates an average electric power of 3.4 W (Vmp: 0.48V, Imp: 7.0 A). The solar cells having various sizes can generate a required amount of electric power according to the amount and connection structure (serial or parallel connection) thereof. In most of solar cell modules installed in various areas such as a building wall, a road, a remote area and so on, a plurality of solar cells are connected to generate a required amount of electric power. However, in the case of the LED or EL device adopted as the light emitting device in the aforementioned embodiments of the invention, the LED consumes electric power of 0.04 W/h and the EL device consumes electric power of 0.1 W/h. Thus, the LED or EL device can be sufficiently turned on in the nighttime using electric power generated only from the specific solar cells. Accordingly, the present invention has yet another aspect of dedicating specific ones of solar cells in a middle or large scale solar cell module for the light emitting device as shown in FIG. 5, such that electric energy generated by the dedicated solar cells can be charged in the capacitor and the like and exclusively used to turn on the light emitting device in the nighttime. As a result, only 0.5 or 1 cell of the plural solar cells can be used efficiently and exclusively for the light emitting device as shown in FIG. 5.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention. Accordingly, it should be construed that those skilled in the art can alter or modify the construction of the solar cell module illustrated in the drawings without departing from the scope of the invention and the scope of the present invention shall be defined only by the appended claims.

### INDUSTRIAL APPLICABILITY

The solar cell module can convert light energy into electric energy and charge at least a portion of the electric energy in a rechargeable battery (or capacitor) in the daytime, such that a light emitting device equipped in the solar cell module can be turned on to emit light using the charged electric energy. It is possible to advantageously promote the aesthetic appearance of the city by using the solar cell module for lighting or decorating purposes in the night or in the middle of night without having to use an additional light source or power source. In addition, it is possible to seal the light emitting device with EVA films, a silicone, an epoxy resin and the like to waterproof the same in order to prevent malfunctions of the solar cell module owing to the permeation of rainwater and the like. Furthermore, the circuit board can automatically discern between day and night (or middle of night) based upon energy input from solar cells without having to use a timer or sensor, and automatically supply charged electric power to the light emitting device to emit light.

1. A solar cell module comprising:
a reinforced glass;
upper and lower Ethylene Vinyl Acetate (EVA) films underlying the reinforced glass;
a plurality of solar cells arranged between the upper and lower EVA films and connected in series or parallel by conductive ribbons to convert solar energy into electric energy;
a backing sheet underlying the lower EVA film;
a control box arranged under the backing sheet, and including a battery or capacitor and a circuit board: and
at least one light emitting device arranged integrally under the reinforced glass, wherein the circuit board controls electric energy, which is charged in the battery or capacitor by the solar cells at daytime, to be applied to the light emitting device at night to turn on the light emitting device,
wherein the circuit board has a switch unit, and through operations of the switch unit, charges electric energy to the battery or capacitor if the electric energy is inputted from the solar cells, and discharges the electric energy from the battery or capacitor to turn on the light emitting device if no electric energy is inputted from the solar cells.

2. The solar cell module according to claim 1, wherein some of the solar cells are dedicated for the light emitting device, such that and electric power generated by the dedicated cells is charged and then exclusively used to power the light emitting device.

3. The solar cell module according to claim 1, wherein the reinforced glass has at least one through hole, in which the light emitting device is inserted.

4. The solar cell module according to claim 3, further comprising a transparent silicone resin for molding the light emitting device inserted into the reinforced glass in order to waterproof the light emitting device.

5. The solar cell module according to claim 1, further comprising a silicone or epoxy resin for molding the control box to waterproof the battery or capacitor and the circuit board arranged in the control box.
